(19) United States
(12) Patent Application Publication
(10) Pub. No.: US 2012/0285621 A1
(43) Pub. Date: Nov. 15, 2012

(54) SEMICONDUCTOR CHAMBER APPARATUS FOR DIELECTRIC PROCESSING

(75) Inventor: Tien Fak Tan, Campbell, CA (US)

(73) Assignee: Applied Materials, Inc., Santa Clara, CA (US)

(21) Appl. No.: 13/112,179

(22) Filed: May 20, 2011

Related U.S. Application Data
(60) Provisional application No. 61/484,284, filed on May 10, 2011.

(51) Int. Cl. H01L 21/3065

(52) U.S. Cl. 156/345.31

(57) ABSTRACT

Systems and chambers for processing dielectric films on substrates are described. Vertical combo chambers include two separate processing chambers vertically arranged in a processing stack. A top processing chamber is configured to process the substrate at relatively low substrate temperature. A robot is configured to remove a substrate from the top processing chamber and change height before placing the substrate in a bottom processing chamber. The bottom processing chamber is configured to anneal the substrate to further process the dielectric film. The vertical stacking increases the number of processing chambers which can be included on a single processing system. The separation of the bottom (annealing or curing) chamber and the top chamber allows the top chamber to remain at a low temperature which hastens the start of a process conducted on a new wafer transferred into the top chamber. This configuration of vertical-combo chamber can be used for depositing a dielectric film in the top chamber and then curing the film in the bottom chamber. The configuration is also helpful for dielectric removal processes which create solid residue, in which case the bottom chamber is used to sublimate the solid residue. The separation limits or substantially eliminates the amount of solid residue which accumulates in the top chamber. Simultaneous processing, thermal separation and contamination control afforded by the design of the vertical combo chambers improve the throughput of a processing system.

### CROSS-REFERENCES TO RELATED APPLICATIONS

This application claims the benefit of U.S. Prov. Pat. App. No. 61/484,284 filed May 10, 2011, and titled “STACKED CHAMBER FOR IMPROVED THROUGHPUT LOW TEMPERATURE ETCH,” which is entirely incorporated herein by reference for all purposes.

### BACKGROUND OF THE INVENTION

Integrated circuits are made possible by processes which produce intricately patterned material layers on substrate surfaces. Producing patterned material on a substrate requires controlled methods for removal of exposed material. Chemical etching is used for a variety of purposes including transferring a pattern in'photoresist into underlying layers, thinning layers or thinning lateral dimensions of features already present on the surface. Often it is desirable to have an etch process which etches one material faster than another helping e.g. a pattern transfer process proceed. Such an etch process is said to be selective to the first material. As a result of the diversity of materials, circuits and processes, etch processes have been developed with a selectivity towards a variety of materials.

A Siconi™ process is a remote plasma process which involves the simultaneous exposure of a substrate to H₂, NF₃ and NH₃ plasma by-products. Remote plasma excitation of the hydrogen and fluorine species allows plasma-damage-free substrate processing. The Siconi™ process is conformal at large length scales. The process is selective towards silicon oxide layers but does not readily remove silicon regardless of whether the silicon is amorphous, crystalline or polycrystalline. The removal selectivity provides advantages for applications such as shallow trench isolation (STI) and inter-layer dielectric (ILD) recess formation.

FIG. 1 shows a flowchart of processing steps for selectively trimming silicon oxide on a patterned substrate. The process begins when a patterned substrate is transferred into the processing chamber (operation 110). The silicon oxide selective dry process begins (operation 120) when plasma by-products are delivered to the processing chamber. The selective process results in the consumption of silicon oxide material (e.g. from within trenches) and the associated production of solid residue above any remaining silicon oxide.

The Siconi™ process produces solid by-products which grow on the surface of the substrate as substrate material is removed. The solid by-products are subsequently removed via sublimation (operation 130) when the temperature of the substrate is raised. The patterned substrate is removed from the processing chamber in operation 140.

Systems are needed to improve substrate processing throughput for a variety of low-temperature dielectric processes which use differing temperatures for two sequential steps.

### BRIEF SUMMARY OF THE INVENTION

Systems and chambers for processing dielectric films on substrates are described. Vertical combo chambers include two separate processing chambers vertically arranged in a processing stack. A top processing chamber is configured to process the substrate at relatively low substrate temperature. A robot is, configured to remove a substrate from the top processing chamber and change height before placing the substrate in a bottom processing chamber. The bottom processing chamber is configured to anneal the substrate to further process the dielectric film. The vertical stacking increases the number of processing chambers which can be included on a single processing system. The separation of the bottom (annealing or curing) chamber and the top chamber allows the top chamber to remain at a low temperature which hastens the start of a process conducted on a new wafer transferred into the top chamber. This configuration of vertical-combo chamber can be used for depositing a dielectric film in the top chamber and then curing the film in the bottom chamber. The configuration is also helpful for dielectric removal processes which create solid residue, in which case the bottom chamber is used to sublimate the solid residue. The separation limits or substantially eliminates the amount of solid residue which accumulates in the top chamber. Simultaneous processing, thermal separation and contamination control afforded by the design of the vertical combo chambers improve the throughput of a processing system.

Embodiments of the invention include substrate processing systems having a remote plasma system configured to receive an upper-chamber precursor and to form a plasma from the upper-chamber precursor to produce plasma effluents. The substrate processing systems have a vertical combo processing chamber including a gas distribution assembly comprising a showerhead. The vertical combo processing chamber also has an upper substrate processing chamber configured to receive and then support an upper substrate during an upper-chamber process. The upper substrate processing chamber is further configured to receive the plasma effluents through the showerhead while processing the upper substrate at an upper substrate temperature below about 100° C. The vertical combo processing chamber also has a lower substrate processing chamber configured to receive and then support a lower substrate during a lower-chamber process. The vertical combo processing chamber further includes a substrate heater configured to heat the lower substrate in the lower substrate processing chamber during the lower-chamber process. The substrate heater is configured to heat the lower substrate above about 100° C. The vertical combo processing chamber further includes a thermal barrier between the upper and lower substrate processing chambers configured to maintain the upper substrate below about 100° C. in the upper substrate processing chamber while the lower substrate is heated above about 100° C. in the lower substrate processing chamber. The substrate processing systems further include a robot configured to remove the upper substrate from the upper substrate processing chamber, lower the upper substrate and place the upper substrate into the lower substrate processing chamber. The substrate processing systems further include a pumping system configured to remove lower-chamber process effluents from the lower substrate processing chamber during the lower-chamber process.

Additional embodiments and features are set forth in part in the description that follows, and in part will become apparent to those skilled in the art upon examination of the specification or may be learned by the practice of the disclosed embodiments. The features and advantages of the disclosed embodiments may be realized and attained by means of the instrumentalities, combinations, and methods described in the specification.

### BRIEF DESCRIPTION OF THE DRAWINGS

A further understanding of the nature and advantages of the disclosed embodiments may be realized by reference to the remaining portions of the specification and the drawings.

FIG. 1 is a flowchart of remote plasma processing steps for processing a substrate.

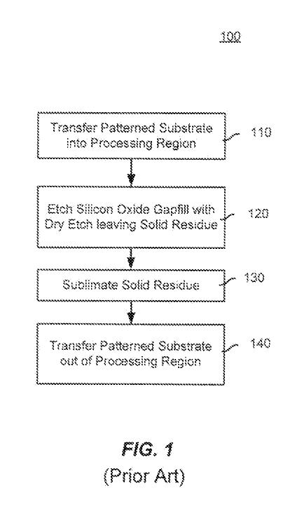

FIG. 2 is a cut-away side view of a vertical combo chamber according to disclosed embodiments.

FIG. 3 is a flow chart for processing a substrate in a vertical combo chamber according to disclosed embodiments.

FIG. 4 is a cross-sectional view of a processing chamber for processing substrates according to disclosed embodiments.

FIG. 5 is a processing system for processing substrates according to disclosed embodiments.

In the appended figures, similar components and/or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

### DETAILED DESCRIPTION OF THE INVENTION

Systems and chambers for processing dielectric films on substrates are described. Vertical combo chambers include two separate processing chambers vertically arranged in a processing stack. A top processing chamber is configured to process the substrate at relatively low substrate temperature. A robot is configured to remove a substrate from the top processing chamber and change height before placing the substrate in a bottom processing chamber. The bottom processing chamber is configured to anneal the substrate to further process the dielectric film. The vertical stacking increases the number of processing chambers which can be included on a single processing system. The separation of the bottom (annealing or curing) chamber and the top chamber allows the top chamber to remain at a low temperature which hastens the start of a process conducted on a new wafer transferred into the top chamber. This configuration of vertical-combo chamber can be used for depositing a dielectric film in the top chamber and then curing the film in the bottom chamber. The configuration is also helpful for dielectric removal processes which create solid residue, in which case the bottom chamber is used to sublimate the solid residue. The separation limits or substantially eliminates the amount of solid residue which accumulates in the top chamber. Simultaneous processing, thermal separation and contamination control afforded by the design of the vertical combo chambers improve the throughput of a processing system.

Siconi™ processes form a subset of remote plasma processes and generally use a hydrogen source such as ammonia (NH₃) in combination with a fluorine source such as nitrogen trifluoride (NF₃). The combination flows into a remote plasma system (RPS) and the plasma effluents created therein are flowed into a substrate processing chamber. The effluents react with exposed silicon oxide to form solid residue which is then sublimated from the surface to complete the removal process. Exposing the silicon oxide to the effluents and sublimating the solid residue can be performed in the same processing chamber. However, the sublimation portion of the process heats up interior components of the chamber. The retained heat may still be present when the next wafer enters the processing chamber. This effect may delay the start of the etch process for the next wafer since the process must begin at a suitably low temperature in order to form solid residue. Solid residue may also remain in the processing chamber following sublimation. This contamination may negatively affect the properties of subsequently processed wafers. The spatial separation of these two processes into a vertical stack addresses the contamination problem and increases throughput per square foot of fab space. The improved throughput results from the simultaneous processing of two substrates per chamber footprint but also from the reduced chemical and thermal cross-talk between the processing chambers.

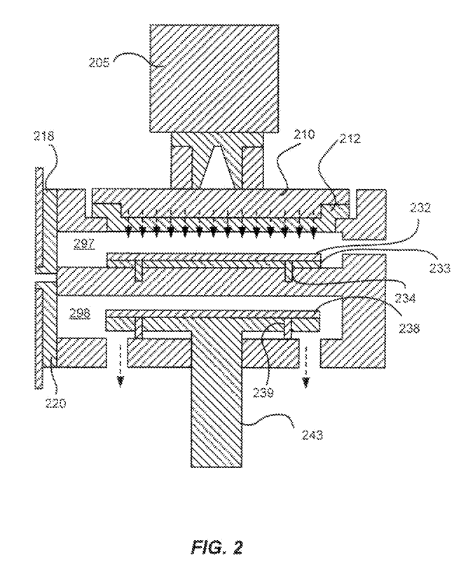

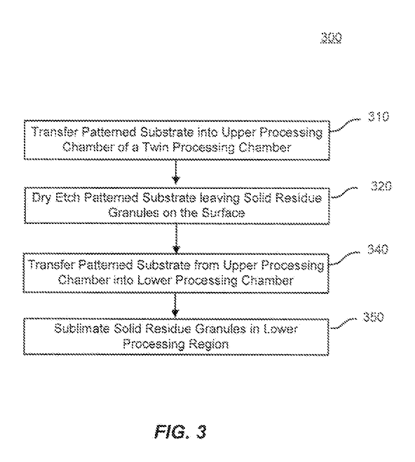

In order to better understand and appreciate the invention, reference is now made to FIGS. 2 and 3 which are a cut-away side view of a vertical combo chamber and a flow chart of an associated remote plasma process, respectively, according to disclosed embodiments. The process begins when a substrate is transferred into an upper substrate processing chamber 297 (operation 310). Top substrate 232 enters upper substrate processing chamber 297 through top chamber slit valve 218. Top chamber slit valve 218 may be opened to allow top substrate 232 to enter upper substrate processing chamber 297. Top chamber slit valve 218 may then be closed to seal the chamber interior from an exterior transfer station (not shown). Upper substrate processing chamber 297 is configured to receive and then support top substrate 232 during processing by first raising top chamber lift pins 234 to receive top substrate 232 from a transfer robot and then lowering top chamber lift pins 234 to put the weight of top substrate 232 on top pedestal 233. Flows of ammonia and nitrogen trifluoride are initiated into remote plasma system 205 outside the vertical combo processing chamber. Plasma effluents are created in remote plasma system 205 and travel through gas box 210 and showerhead 212 before entering upper substrate processing chamber 297. Gas box 210 and showerhead 212 may collectively be referred to as the gas distribution assembly herein.

Upper substrate processing chamber 297 is used to remove dielectric from top substrate 232 but may generally a solid by-product formation or deposition chamber. Top substrate 232 is processed in upper substrate processing chamber 297 by introducing the plasma effluents into upper substrate processing chamber 297 through showerhead 212 (operation 320). The plasma effluents interact with the substrate to remove material (e.g. silicon oxide) while producing solid residue on the surface (operation 320). The substrate temperature needs to be kept relatively low (near room temperature) otherwise the solid residue is not formed and the removal rate may drop. The temperature of the substrate during the interaction with the plasma effluents may be below one of 60° C., 50° C., 40° C. or 35° C. in different embodiments.

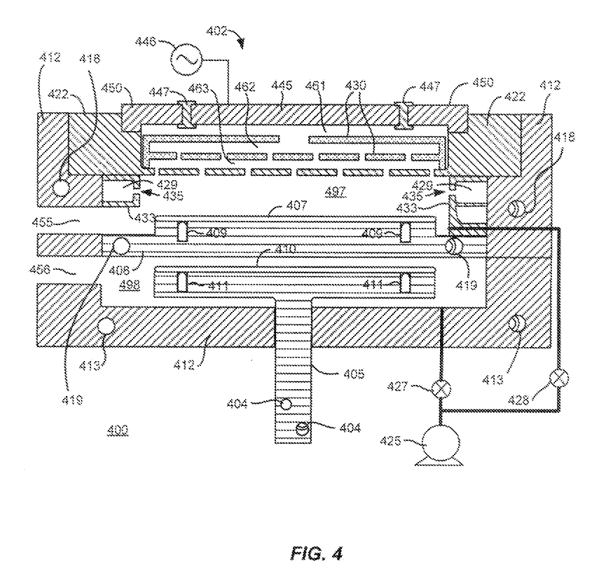

Remote plasma system 205 is used to produce the plasma effluents and may be referred to as a remote plasma system herein to indicate that it is somehow separated from the upper substrate processing chamber. Remote plasma system 205 may be a distinct module from the upper substrate processing chamber (as shown in FIG. 2) or a compartment within upper substrate processing chamber 297 partitioned from upper substrate processing chamber 297 by a showerhead. One such alternative embodiment will be described shortly with reference to FIG. 4.

Top substrate 232 is removed from upper substrate processing chamber 297 once the formation of solid by-products is completed (operation 340) and transferred into lower substrate processing chamber 298. Sublimation chamber slit valve 220 is opened to allow the substrate to enter lower substrate processing chamber 298. Lower substrate processing chamber 298 receives bottom substrate 238 on sublimation chamber lift pins 239 which are lowered to transfer the weight of bottom substrate 238 onto sublimation pedestal 238. Sublimation chamber slit valve 220 is then closed to seal lower substrate processing chamber 298 from the exterior transfer station. The same transfer robot may be used to retrieve the substrate from the upper substrate processing chamber and place it in the lower substrate processing chamber. The transfer robot may move up or down to access either the upper or lower substrate processing chambers. The robot may be configured to move up and down more than 15 cm, more than 20 cm or more than 25 cm in disclosed embodiments. The same substrate is processed in both the upper substrate processing chamber 297 and the lower substrate processing region 298, however, different reference numerals are employed (232 and 238) in order to facilitate the description of the apparatus. The reference numeral is associated with the substrate position appropriate for the associated discussion.

Bottom pedestal 243 has a bottom substrate heater proximal, embedded within or attached to the pedestal. In this way, bottom pedestal 243 is configured to raise the temperature of bottom substrate 238 above the sublimation temperature associated with the solid residue. Performing sublimation in a separate region allows upper substrate processing chamber 297 and associated interior components to remain cool while the substrate is transferred and then heated in lower substrate processing chamber 298. Bottom substrate 238 is heated inside lower substrate processing chamber 298 to sublimate the solid by-products (operation 350). The solid residue is removed by sublimation, during which, the temperature of the solid residue and the substrate may be raised above one of 90° C., 100° C., 120° C. or 140° C. in different embodiments. The duration of the sublimation may be above one of 45 seconds, 60 seconds, 75 seconds, 90 seconds or 120 seconds, in different embodiments.

During this time, another substrate may be placed in upper substrate processing chamber 297 and processed. The vertical combo processing is arranged with a spatial separation as well as a wall between upper substrate processing chamber 297 and lower substrate processing chamber 298. The wall comprises or consists essentially of top pedestal 233 in disclosed embodiments. Both the spatial separation and the wall constitute a thermal barrier as described herein. The thermal barrier between the upper and lower substrate processing chambers is configured to maintain the temperature of the top substrate (the one being processed by plasma effluents in this example) below the sublimation temperature despite the concurrent heating occurring on the lower substrate (the one being annealed/sublimated). While the lower substrate is at the elevated temperatures already recited, the upper substrate may be processed at a temperature below one of 60° C., 50° C., 40° C. or 35° C. in different embodiments.

Lower substrate processing chamber 298 is located below upper substrate processing chamber 297 in order to lower the area required for the vertical combo processing chamber. Lower substrate processing chamber 298 may be directly below upper substrate processing chamber 297. Top substrate 232 and bottom substrate 238 are coaxial in embodiments. The vertical combo processing chamber is configured to simultaneously process two substrates at a time, enhancing throughput for a given area of cleanroom space. The temperature of components within upper substrate processing chamber 297 is not raised above the sublimation temperature in embodiments, which allows processing to continue without a cooling delay. Mitigating the need for cooling time further increases the throughput per square foot. Vertical combo chambers may be paired up to form twin chambers which allow a substrate throughput greater than 150 wafers per hour (wph), greater than 180 wph or greater than 210 wph in disclosed embodiments. Systems may be configured to have three such twin combo chambers processing simultaneously to achieve a substrate throughput greater than 450 wph, greater than 540 wph or greater than 630 wph in disclosed embodiments.

Solid residue is predominantly sublimated in lower substrate processing chamber 298.

Upper substrate processing chamber 297 is only used for the solid by-product formation step and not sublimation, significantly reducing the amount of solid residue which may build-up on the interior surfaces of upper substrate processing chamber 297. The reduction in build-up may decrease the requirement on frequency of the preventative maintenance cleaning procedure for at least the upper substrate processing chamber 297.

Generally speaking, vertical combo processing chambers may be used for processes other than removing dielectric material. For example, vertical combo processing chambers may also be used to deposit dielectric material in the top processing chamber and cure the dielectric material in the bottom processing chamber. The bottom substrate may be annealed at a substrate temperature greater than or about one of 90° C., 100° C., 120° C., 150° C., 180° C., 200° C., or 240° C. in different embodiments. While the bottom substrate is at the elevated temperatures already recited, the upper substrate may be processed at a temperature below one of 100° C., 80° C., 60° C., 50° C., 40° C. or 35° C. in different embodiments Any of the upper limits may be combined with any of the lower limits to form additional thermal ranges for the two substrates according to disclosed embodiments.

Additional chamber properties and components are disclosed in the course of describing an alternative processing system.

### Exemplary Processing System

FIG. 4 is a partial cross sectional view showing an illustrative vertical combo processing chamber 400 according to embodiments of the invention. In this exemplary embodiment, the vertical combo processing chamber 400 includes a chamber body 412, a lid assembly 402, and two substrate processing chambers (upper 497 and lower 498). The lid assembly 402 is disposed at an upper end of the chamber body 412, and the two substrate processing chambers 497-498 are disposed within the chamber body 412. The vertical combo processing chamber 400 and the associated hardware are preferably formed from one or more process-compatible materials (e.g. aluminum, stainless steel, etc.).

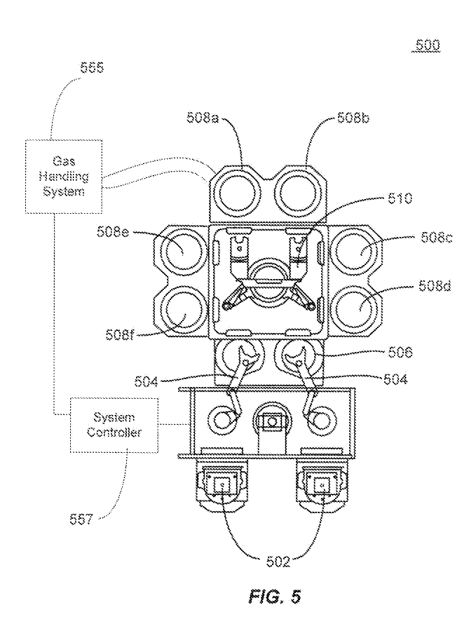

The chamber body 412 includes top chamber slit valve opening 455 formed in a sidewall thereof to provide access to upper substrate processing chamber 497. Upper substrate 407 may be transferred into upper substrate processing chamber 497 through top chamber slit valve opening 455 by a transfer robot as described with reference to FIG. 2. Upper substrate 407 is received on upper chamber lift pins 409 which are then lowered to transfer the weight of upper substrate 407 onto top pedestal 408. In other embodiments, lift pins are not employed but upper substrate 407 is transferred directly onto the surface of top pedestal 408. Top chamber slit valve opening 455 is selectively opened and closed to allow access to upper substrate processing chamber 497 by a wafer handling robot (not shown). In one embodiment, a wafer can be transported in and out of upper substrate processing chamber 497 through, top chamber slit valve opening 455 and into one of lower substrate processing chamber 498, an adjacent transfer chamber and/or load-lock chamber, or another chamber within a cluster tool. An exemplary cluster tool which may include vertical combo processing chamber 400 is shown in FIG. 5.

In one or more embodiments, chamber body 412 includes a lower chamber body channel 413 for flowing a heat transfer fluid through chamber body 412. The heat transfer fluid can be a heating fluid or a coolant and is used to control the temperature of chamber body 412 during processing and substrate transfer. Heating the chamber body 412 may help to prevent unwanted condensation of the gas or byproducts on the chamber walls. Exemplary heat transfer fluids include water, ethylene glycol, or a mixture thereof. These fluids can also be used to simultaneously cool other portions of vertical combo processing chamber 400. An exemplary heat transfer fluid may also include nitrogen gas.

The chamber body 412 can further include a liner 433 that surrounds top pedestal 408. The liner 433 is preferably removable for servicing and cleaning. The liner 433 can be made of a metal such as aluminum, or a ceramic material. However, the liner 433 can be any process compatible material. The liner 433 can be bead blasted to increase the adhesion of any material deposited thereon, thereby preventing flaking of material which results in contamination of upper substrate processing chamber 497. In one or more embodiments, the liner 433 includes one or more apertures 435 and a pumping channel 429 formed therein that is in fluid communication with a vacuum system. The apertures 435 provide a flow path for gases into pumping channel 429, which provides egress for the gases within upper substrate processing chamber 497. The vacuum system can include a vacuum pump 425 and upper chamber throttle valve 428 to regulate flow of gases through the upper substrate processing chamber 497. The vacuum pump 425 is coupled to pumping channel 429 within liner 433 by way of upper chamber throttle valve 428.

Apertures 435 allow the pumping channel 429 to be in fluid communication with upper substrate processing chamber 497 within chamber body 412. Upper substrate processing chamber 497 is defined by a lower surface of showerhead 422 and an upper surface of top pedestal 408, and is surrounded by the liner 433. The apertures 435 may be uniformly sized and evenly spaced about the liner 433. However, any number, position, size or shape of apertures may be used, and each of those design parameters can vary depending on the desired flow pattern of gas across the substrate receiving surface as is discussed in more detail below. In addition, the size, number and position of the apertures 435 are configured to achieve uniform flow of gases exiting upper substrate processing chamber 497. Further, the aperture size and location may be configured to provide rapid or high capacity pumping to facilitate a rapid exhaust of gas from upper substrate processing chamber 497. For example, the number and size of apertures 435 in close proximity to the vacuum port(s) may be smaller than the size of apertures 435 positioned farther away from the vacuum port(s) leading to upper chamber throttle valve 428.

A gas supply panel (not shown) is typically used to provide process gas(es) to upper substrate processing chamber 497 through one or more apertures. Generally, a hydrogen-containing precursor and a fluorine-containing precursor may be introduced through one or more apertures in lid assembly 402 into remote plasma region(s) 461-463 and excited by plasma power source 446 to produce plasma effluents. The remote plasma regions used to produce plasma effluents are collectively be referred to as the remote plasma system. The particular gas or gases that are used depend upon the process or processes to be performed within the upper substrate processing chamber 497. Illustrative gases can include, but are not limited to one or more precursors, reductants, catalysts, carriers, purge, cleaning, or any mixture or combination thereof. Typically, the one or more gases introduced to upper substrate processing chamber 497 flow into plasma volume 461 through aperture(s) in top plate 450. Electronically operated valves and/or flow control mechanisms (not shown) may be used to control the flow of gas from the gas supply into upper substrate processing chamber 497. Depending on the specifics of the solid by-product formation process, any number of gases can be delivered to upper substrate processing chamber 497.

Generally speaking, a fluorine-containing precursor may be combined with a hydrogen-containing precursor in the remote plasma system to form the plasma effluents used for the solid by-product formation processes. The fluorine-containing precursor may include one or more of nitrogen trifluoride, hydrogen fluoride, diatomic fluorine, monatomic fluorine and fluorine-substituted hydrocarbons. The hydrogen-containing precursor may include one or more of atomic hydrogen, molecular hydrogen, ammonia, a hydrocarbon and an incompletely halogen-substituted hydrocarbon. Plasma effluents include a variety of molecules, molecular fragments and ionized species. Currently entertained theoretical mechanisms of Siconi™ processes may or may not be entirely correct but plasma effluents are thought to include NH₄F and NH₄F.HF which react readily with low temperature substrates described herein. Plasma effluents may react with a silicon oxide surface to form (NH₄)₂SiF₆, NH₃ and H₂O products. The NH₃ and H₂O are vapors under the processing conditions described herein and may be removed from upper substrate processing chamber 497 by vacuum pump 425. These process effluents and any other upper-chamber process gases may be referred to as upper-chamber process effluents which may be removed through vacuum pump 425. A thin continuous or discontinuous layer of (NH₄)₂SiF₆ solid by-products is left behind on the substrate surface.

Lid assembly 402 can further include electrode 445 to generate a plasma of reactive species within lid assembly 402. In one embodiment, electrode 445 is supported by top plate 450 and is electrically isolated therefrom by electrically isolating ring(s) 447 made from aluminum oxide or any other insulating and process compatible material. In one or more embodiments, electrode 445 is coupled to a power source 446 while the rest of lid assembly 402 is connected to ground. Accordingly, a plasma of one or more process gases can be generated in remote plasma system composed of volumes 461, 462 and/or 463 between electrode 445 and showerhead 422. For example, the plasma may be initiated and maintained between electrode 445 and one or both blocker plates of blocker assembly 430. Alternatively, the plasma can be struck and contained between electrode 445 and showerhead 422, in the absence of blocker assembly 430. In either embodiment, the plasma is well confined or contained within lid assembly 402. Accordingly, the plasma is a “remote plasma” since no active plasma is in direct contact with the substrate disposed within the chamber body 412. As a result, plasma damage to the substrate may be avoided since the plasma is separated from the substrate surface.

Production of the plasma effluents occurs within volumes 461, 462 and/or 463 by applying plasma power to electrode 445 relative to the rest of lid assembly 402. Plasma power can be a variety of frequencies or a combination of multiple frequencies. In the exemplary processing system the plasma is provided by RF power delivered to electrode 445. The RF power may be between about 1 W and about 1000 W, between about 5 W and about 600 W, between about 10 W and about 300 W or between about 20 W and about 100 W in different embodiments. The RF frequency applied in the exemplary processing system may be less than About 200 kHz, less than about 150 kHz, less than about 120 kHz or between about 50 kHz and about 90 kHz in different embodiments.

Upper substrate processing chamber 497 can be maintained at a variety of pressures during the flow of carrier gases and/or plasma effluents into upper substrate processing chamber 497. The pressure may be maintained between about 500 mTorr and about 30 Torr, between about 1 Torr and about 10 Torr or between about 3 Torr and about 6 Torr in different embodiments. Lower pressures may also be used within upper substrate processing chamber 497. The pressure may be maintained below or about 500 mTorr, below or about 250 mTorr, below or about 100 mTorr, below or about 50 mTorr or below or about 20 mTorr in different embodiments.

A wide variety of power sources 446 are capable of activating the hydrogen-containing precursor (e.g. ammonia) and the nitrogen-containing precursor (e.g. nitrogen trifluoride). For example, radio frequency (RF), direct current (DC), or microwave (MW) based power discharge techniques may be used. The activation may also be generated by a thermally based technique, a gas breakdown technique, a high intensity light source (e.g., UV energy), or exposure to an x-ray source. Alternatively, a remote activation source may be used, such as a remote plasma generator, to generate a plasma of reactive species which are then delivered into upper substrate processing chamber 497. Exemplary remote plasma generators are available from vendors such as MKS Instruments, Inc., Advanced Energy Industries, Inc as well as from Applied Materials. In the exemplary processing system an RF power supply is coupled to electrode 445.

During exposure to plasma effluents, upper substrate 407 may be maintained below the temperatures given previously, between about 15° C. and about 50° C., between about 22° C. and about 40° C., or near 30° C. in different embodiments. An additional independent temperature control channel (not shown) may be formed in top pedestal 408 to provide additional control of the temperature of upper substrate 407. The temperatures of the process chamber body 412 and the lower substrate 410 may also be controlled by flowing a heat transfer medium through lower chamber body channel 413 and bottom pedestal channel 404, respectively. Bottom pedestal 20. channel 404 may be formed within bottom pedestal 405 to facilitate the transfer of thermal energy. Chamber body 412, top pedestal 408 and bottom pedestal 405 may be cooled or heated independently. For example, a heating fluid may be flown through bottom pedestal 405 while cooling fluids are flown through the others. The heating fluid may be heated in a heating unit (not shown) before passing through bottom pedestal channel 404. In an embodiment, a single cooling channel is formed in both the upper and lower substrate processing chambers and a cooling fluid cooled in a cooling unit is transferred into and through the single cooling channel.

Upper substrate 407 is removed from upper substrate processing chamber 497 once the solid by-product formation process is completed and transferred into lower substrate processing chamber 498. Upper substrate 407 is removed through top chamber slit valve opening 455 and inserted through sublimation chamber slit valve opening 456 into lower substrate processing chamber 498. During or after the transfer, upper substrate 407 is referred to as lower substrate 410 in order to reflect the change in location. Another substrate is transferred into upper substrate processing chamber 497 so two substrates are simultaneously processed in vertical combo processing chamber 400. Upper chamber lift pins 409 and lower chamber lift pins 411 may be used to facilitate the transfer of the substrates to and from a transfer robot (not shown).

Lower substrate processing chamber 498 receives lower substrate 410 on lower chamber lift pins 411 which retract to transfer the weight of lower substrate 410 onto bottom pedestal 405. Sublimation chamber slit valve opening 456 is then sealed to isolate lower substrate processing chamber 498 from the exterior transfer station which contains the transfer robot. The same transfer robot may be used to retrieve the substrate from upper substrate processing chamber 497 and place it in lower substrate processing chamber 498. The transfer robot may move up or down to access either the upper or lower substrate processing chambers (497, 498). The same substrate is processed in both the upper substrate processing chamber 497 and the lower substrate processing region 498, however, different reference numerals are employed (407 and 410) in order to facilitate the description of the apparatus. The reference numeral is associated with the substrate position appropriate for the associated process and discussion. Upper substrate processing chamber 497 is configured to be sealable from the lower substrate processing chamber in disclosed embodiments. Both processing chambers may also be configured to be sealable from the surrounding atmosphere.

Bottom pedestal 405 has bottom pedestal channel 404 for carrying the heat transfer fluid to heat bottom pedestal 405 and lower substrate 410. In this way, bottom pedestal 405 is configured to raise the temperature of lower substrate 410 above the sublimation temperature associated with the solid residue formed during the process performed in upper substrate processing chamber 497. Performing sublimation in a separate region allows upper substrate processing chamber 497 and associated interior components to remain cool while the substrate is transferred and then heated in lower substrate processing chamber 498. Lower substrate 410 is heated inside lower substrate processing chamber 498 to remove the solid by-products. The process parameters described in association with FIGS. 2-3 describe sublimation processes performed in lower substrate processing chamber 498 in disclosed embodiments. The solid by-products may be removed through a separate pumping system from the pumping system used to evacuate material from upper substrate processing chamber 497 in order to further isolate the processes performed in each processing chamber. In another embodiment, the same processing system is used as shown in FIG. 4. Lower chamber throttle valve 427 may be opened to allow removal of the solid by-products using vacuum pump 425. Solid by-products and other lower-chamber process gases may be referred to as lower-chamber process effluents which are then removed through vacuum pump 425.

Other methods may be used to control the substrate temperature. The substrate may be heated by heating the bottom pedestal 405 (or a portion thereof, such as a pedestal) with a resistive heater or by some other means. In another configuration, a local heater (not shown) above lower substrate 410 may be used to raise the temperature of lower substrate 410 in lower substrate processing chamber 498. In this case, the lower substrate 410 may be heated radiatively. The substrate may be elevated by raising bottom pedestal 405 or by using lift pins 411 to bring lower substrate 410 closer to the radiative heater thereby increasing the temperature. Due to the separation of upper substrate processing chamber 497 and lower substrate processing chamber 498, the substrate may be heated more rapidly without the precautions necessary when the same chamber is used for solid by-product formation and sublimation. A convection heater may also be used which transfers heat to lower substrate 410 predominantly through gases present in lower substrate processing chamber 498. A convection heater may be heated to between about 100° C. and 150° C., between about 110° C. and 140° C. or between about 120° C. and 130° C. in different embodiments. By reducing the separation between lower substrate 410 and the convection heater, lower substrate 410 is heated to a higher temperatures as the separation is reduced.

Regardless of the method of heating, lower substrate 410 may be heated to above about above about 90° C., above about 100° C. or between about 115° C. and about 150° C. in different embodiments. The temperature of lower substrate 410 during the sublimation step is sufficient to dissociate or sublimate solid (NH₄)₂SiF₆ on the substrate into volatile SiF₄, NH₃ and HF products which may be pumped away from lower substrate processing chamber 498.

Top pedestal channel 419 is included inside top pedestal 408 to provide a path for a cooling fluid in disclosed embodiments. Upper substrate 407 is processed at the solid by-product formation processing temperatures described herein concurrently with the elevated sublimation processing of lower substrate 410. Inclusion of top pedestal channel 419 is one way of ensuring upper substrate 407 and lower substrate 410 may be simultaneously processed. Alternatively or in combination, upper chamber cooling channel 418 may be formed in the top portion of vertical combo processing chamber 400 to maintain a relatively low temperature for upper substrate processing chamber 497 and upper substrate 407. Top pedestal channel 419 and upper chamber cooling channel 418 may be separate or the two channels may be combined into a single cooling channel which carries, a cooling fluid to maintain the relatively low temperatures recited herein.

Lower substrate processing chamber 498 may include a lower chamber body channel 413 and a heating unit (not shown) configured to heat a heating fluid. In this case, the lower chamber body channel receives the heating fluid after the heating fluid passes through the heating unit. Similarly, upper substrate processing chamber 497 may include upper chamber body channel 418 and a cooling unit (not shown) configured to cool a cooling fluid. The upper chamber body channel receives the cooling fluid after the cooling fluid passes through the cooling unit.

Nitrogen trifluoride (or another fluorine-containing precursor) may be flowed into remote plasma volume 461 at rates between about 25 sccm and about 200 sccm, between about 50 sccm and about 150 sccm or between about 75 sccm and about 125 sccm in different embodiments. Ammonia (or hydrogen-containing precursors in general) may be flowed into remote plasma volume 461 at rates between about 50 sccm and about 300 sccm, between about 75 sccm and about 250 sccm, between about 100 seem and about 200 sccm or between about 120 sccm and about 170 sccm in different embodiments. Combined flow rates of hydrogen-containing and fluorine-containing precursors into the remote plasma system may account for 0.05% to about 20% by volume of the overall gas mixture; the remainder being a carrier gas. In one embodiment, a purge or carrier gas is first initiated into the remote plasma system before those of the reactive gases to stabilize the pressure within the remote plasma system.

In one or more embodiments, the vertical combo processing chamber 400 can be integrated into a variety of multi-processing platforms, including the Producer™ GT, Centura™ AP and Endura™ platforms available from. Applied Materials, Inc. located in Santa Clara, Calif. Such a processing platform is capable of performing several processing operations without breaking vacuum.

Deposition chambers that may implement embodiments of the present invention may include dielectric etch chambers, high-density plasma chemical vapor deposition (HDP-CVD) chambers, plasma enhanced chemical vapor deposition (PECVD) chambers, sub-atmospheric chemical vapor deposition (SACVD) chambers, and thermal chemical vapor deposition chambers, among other types of chambers.

Embodiments of the deposition systems may be incorporated into larger fabrication systems for producing integrated circuit chips. FIG. 5 shows one such system 500 of deposition, baking and curing chambers according to disclosed embodiments. In the figure, a pair of FOUPs (front opening unified pods) 502 supply substrate substrates (e.g., 300 mm diameter wafers) that are received by robotic arms 504 and placed into a low pressure holding area 506 before being placed into one of the wafer processing chambers 508a-f. A second robotic arm 510 may be used to transport the substrate wafers from the holding area 506 to the processing chambers 508a-f and back. Each processing chamber 508a-f, can be outfitted to perform a number of substrate processing operations including the remote plasma processes described herein in addition to cyclical layer deposition (CLD), atomic layer deposition (ALD), chemical vapor deposition (CVD), physical vapor deposition (PVD), etch, pre-clean, degas, orientation and other substrate processes.

The processing chambers 508a-f may include one or more system components for depositing, annealing, curing and/or etching a flowable dielectric film on the substrate wafer. In one configuration, two pairs of the processing chamber (e.g., 508c-d and 508e-f) may be used to deposit dielectric material on the substrate, and the third pair of processing chambers (e.g., 508a-b) may be used to etch the deposited dielectric. In another configuration, all three pairs of chambers (e.g., 508a-f) may be configured to etch a dielectric film on the substrate. Any one or more of the processes described may be carried out on chamber(s) separated from the fabrication system shown in different embodiments.

System controller 557 is used to control motors, valves, flow controllers, power supplies and other functions required to carry out process recipes described herein. A gas handling system 555 may also be controlled by system controller 557 to introduce gases to one or all of the processing chambers 508a-f. System controller 557 may rely on feedback from optical sensors to determine and adjust the position of movable mechanical assemblies in gas handling system 555 and/or in processing chambers 508a-f. Mechanical assemblies may include the robot, throttle valves and susceptors which are moved by motors under the control of system controller 557.

In an exemplary embodiment, system controller 557 includes a hard disk drive (memory), USB ports, a floppy disk drive and a processor. System controller 557 includes analog and digital input/output boards, interface boards and stepper motor controller boards. Various parts of multi-chamber processing system 500 which contains vertical combo processing chamber 400 are controlled by system controller 557. The system controller executes system control software in the form of a computer program stored on computer-readable medium such as a hard disk, a floppy disk or a flash memory thumb drive. Other types of memory can also be used. The computer program includes sets of instructions that dictate the timing, mixture of gases, chamber pressure, chamber temperature, RF power levels, susceptor position, and other parameters of a particular process.

A process for etching, depositing or otherwise processing a film on a, substrate or a process for cleaning chamber can be implemented using a computer program product that is executed by the controller. The computer program code can be written in any conventional computer readable programming language: for example, 68000 assembly language, C, C++, Pascal, Fortran or others. Suitable program code is entered into a single file, or multiple files, using a conventional text editor, and stored or embodied in a computer usable medium, such as a memory system of the computer. If the entered code text is in a high level language, the code is compiled, and the resultant compiler code is then linked with an object code of precompiled Microsoft Windows® library routines. To execute the linked, compiled object code the system user invokes the object code, causing the computer system to load the code in memory. The CPU then reads and executes the code to perform the tasks identified in the program.

The interface between a user and the controller may be via a touch-sensitive monitor and may also include a mouse and keyboard. In one embodiment two monitors are used, one mounted in the clean room wall for the operators and the other behind the wall for the service technicians. The two monitors may simultaneously display the same information, in which case only one is configured to accept input at a time. To select a particular screen or function, the operator touches a designated area on the display screen with a finger or the mouse. The touched area changes its highlighted color, or a new menu or screen is displayed, confirming the operator's selection.

The terms “gas” and “gases” are used interchangeably, unless otherwise noted, and refer to one or more reactants, catalysts, carrier, purge, cleaning, combinations thereof, as well as any other fluid introduced into upper substrate processing chamber 497. The term “precursor” is used to refer to any process gas which takes part in a reaction to either remove or deposit material from a surface. As used herein “substrate” may be a support substrate with or without layers formed thereon. The support substrate may be an insulator or a semiconductor of a variety of doping concentrations and profiles and may, for example, be a semiconductor substrate of the type used in the manufacture of integrated circuits. “Silicon oxide” may include minority concentrations of other elemental constituents such as nitrogen, hydrogen, carbon and the like. A gas may be a combination of two or more gases. The term “trench” is used throughout with no implication that the etched geometry has a large horizontal aspect ratio. Viewed from above the surface, trenches may appear circular, oval, polygonal, rectangular, or a variety of other shapes.

Having disclosed several embodiments, it will be recognized by those of skill in the art that various modifications, alternative constructions, and equivalents may be used without departing from the spirit of the disclosed embodiments. Additionally, a number of well known processes and, elements have not been described in order to avoid unnecessarily obscuring the present invention. Accordingly, the above description should not be taken as limiting the scope of the invention.

Where a range of values is provided, it is understood that each intervening value, to the tenth of the unit of the lower limit unless the context clearly dictates otherwise, between the upper and lower limits of that range is also specifically disclosed. Each smaller range between any stated value or intervening value in a stated range and any other stated or intervening value in that stated range is encompassed. The upper and lower limits of these smaller ranges may independently be included or excluded in the range, and each range where either, neither or both limits are included in the smaller ranges is also encompassed within the invention, subject to any specifically excluded limit in the stated range. Where the stated range includes one or both of the limits, ranges excluding either or both of those included limits are also included.

As used herein and in the appended claims, the singular forms “a”, “an”, and “the” include plural referents unless the context clearly dictates otherwise. Thus, for example, reference to “a process” includes a plurality of such processes and reference to “the dielectric material” includes reference to one or more dielectric materials and equivalents thereof known to those skilled in the art, and so forth.

Also, the words “comprise,” “comprising,” “include,” “including,” and “includes” when used in this specification and in the following claims are intended to specify the presence of stated features, integers, components, or steps, but they do not preclude the presence or addition of one or more other features, integers, components, steps, acts, or groups.

What is claimed is:

1. A substrate processing system comprising:
a remote plasma system configured to receive an upper-chamber precursor and to form a plasma from the upper-chamber precursor to produce plasma effluents;
a vertical combo processing chamber comprising
a gas distribution assembly comprising a showerhead,
an upper substrate processing chamber configured to receive and then support an upper substrate on an upper pedestal during an upper-chamber process, wherein the upper substrate processing chamber is further configured to receive the plasma effluents through the showerhead while processing the upper substrate at an upper substrate temperature below about 100° C.,
a lower substrate processing chamber configured to receive and then support a lower substrate on a lower pedestal during a lower-chamber process,
a substrate heater configured to heat the lower substrate in the lower substrate processing chamber during the lower-chamber process, wherein the substrate heater is configured to heat the lower substrate above about 100° C., and
a thermal barrier between the upper and lower substrate processing chambers configured to maintain the upper substrate below about 100° C. in the upper substrate processing chamber while the lower substrate is concurrently heated above about 100° C. in the lower substrate processing chamber;
a robot configured to remove the upper substrate from the upper substrate processing chamber, lower the upper substrate and place the upper substrate into the lower substrate processing chamber; and
a pumping system configured to remove lower-chamber process effluents from the lower substrate processing chamber during the lower-chamber process.

2. The substrate processing system of claim 1 wherein the thermal barrier between the upper and lower substrate processing chambers is configured to maintain the upper substrate below about 60° C. in the upper substrate processing chamber while concurrently heating the lower substrate above about 100° C. in the lower substrate processing chamber.

3. The substrate processing system of claim 1 wherein the thermal barrier between the upper and lower substrate processing chambers is configured to maintain the upper substrate below about 100° C. in the upper substrate processing chamber while concurrently heating the lower substrate above about 150° C. in the lower substrate processing chamber.

4. The substrate processing system of claim 1 wherein the thermal barrier between the upper and lower substrate processing chambers is configured to maintain the upper substrate below about 100° C. in the upper substrate processing chamber while concurrently heating the lower substrate above about 200° C. in the lower substrate processing chamber.

5. The substrate processing system of claim 1 wherein the thermal barrier between the upper and lower substrate, processing chambers is configured to maintain the upper substrate below about 60° C. in the upper substrate processing chamber while concurrently heating the lower substrate above about 200° C. in the lower substrate processing chamber.

6. The substrate processing system of claim 1 wherein the upper substrate processing chamber is configured to be sealable from the lower substrate processing chamber.

7. The substrate processing system of claim 1 wherein both processing chambers are configured to be sealable from the surrounding atmosphere.

8. The substrate processing system of claim 1 wherein the pumping system is further, configured to remove upper-chamber process effluents from the upper substrate processing chamber during the upper-chamber process.

9. The substrate processing system of claim 1 wherein the vertical combo processing chamber further comprises a chamber body channel and the substrate processing system further comprises a cooling unit configured to cool a cooling fluid, wherein the chamber body channel is configured to receive the cooling fluid after the cooling fluid passes through the cooling unit.

10. The substrate processing system of claim 1 wherein the upper substrate processing chamber further comprises an upper chamber body channel and a cooling unit configured to cool a cooling fluid, wherein the upper chamber body channel is configured to receive the cooling fluid after the cooling fluid passes through the cooling unit.

11. The substrate processing system of claim 1 wherein the lower substrate processing chamber further comprises a lower chamber channel and a heating unit configured to heat a heating fluid, wherein the lower chamber channel is configured to receive the heating fluid after the heating fluid passes through the heating unit.

12. The substrate processing system of claim 1 wherein the upper-chamber precursors comprise a fluorine-containing precursor and a hydrogen-containing precursor.

13. The substrate processing system of claim 1 wherein the robot is further configured to remove the lower substrate from the lower substrate processing chamber.

14. The substrate processing system of claim 1 wherein the substrate heater comprises a bottom pedestal channel configured to receive a heating fluid heated within a heating unit.

15. The substrate processing system of claim 1 wherein the substrate heater is configured to heat the lower substrate radiatively.

16. The substrate processing system of claim 1 wherein the substrate heater is configured to heat the lower substrate convectively.
